(19) United States
(12) Patent Application Publication
(10) Pub. No.: US 2019/0293684 A1
(43) Pub. Date: Sep. 26, 2019

(54) CONTACT CONDUCTION JIG AND INSPECTION DEVICE

(71) Applicant: NIDEC READ CORPORATION, Kyoto (JP)

(72) Inventor: Kiyoshi NUMATA, Kyoto (JP)

(21) Appl. No.: 16/305,408

(22) PCT Filed: Apr. 26, 2017
(86) PCT No.: PCT/JP2017/016548

§ 371 Date: Nov. 29, 2018

(30) Foreign Application Priority Data
May 31, 2016 (JP) 2016-109135

(51) Int. Cl. G01R 1/067; G01R 1/073; G01R 31/26; H01R 33/76

(52) U.S. Cl. CPC G01R 1/06722; G01R 1/073; H01R 2201/20; H01R 33/76; G01R 31/26

(57) ABSTRACT

An inspection jig may include: a support plate including a plate-shaped member and having a plurality of through holes extending along a thickness of the support plate; a plurality of probes each having a tubular shape and conductivity, the probes being respectively inserted into the through holes; and an elastomer elastically holding the probes in the through holes. Each of the probes may include a first spring part wound helically in a first direction and configured to expand and contract along an axis of the probe.

### CROSS-REFERENCE TO RELATED APPLICATIONS

This application is a national stage entry according to 35 U.S.C. 371 of PCT Application No. PCT/JP2017/016548 filed on Apr. 26, 2017, which claims priority to Japanese Application No. 2016-109135 filed on May 31, 2016, which are entirely incorporated herein by reference.

### TECHNICAL FIELD

The present disclosure relates to a contact conduction jig for contact with a target object, and an inspection device including the contact conduction jig.

### BACKGROUND

A probe unit in which a plurality of probes made expandable and contractable by coil springs may be held in a casing, and a tip portion of each probe may be brought into contact with a conductive pad to be inspected (see, for example, Patent Literature 1). According to this probe unit, the expansion and contraction of the coil springs enables the adaptation to variations in height of electrode pads (i.e., variations in position of electrode pads in a direction along an axis of each probe). In addition, a rod-shaped terminal made expandable and contractable by such a coil spring may be occasionally used as a connection terminal or a connector for establishing an electrical connection between two points, rather than as a probe for inspection.
Patent Literature 1: JP 2007-24664 A

### SUMMARY

Recently, connection objects to be inspected or to be connected have been made finer. In order to bring the above-described probe unit into contact with such fine connection objects, the coil springs may also have a fine structure. Therefore, the coil springs may be made finer. The use of the fine coil springs causes a reduction in displacement for expansion and contraction of the probes. This may result in a reduction in ability of the probe unit to adapt to variations in height of the contact objects.

The present disclosure provides a contact conduction jig and an inspection device that facilitate improvement in their abilities to adapt to variations in height of contact objects.

A contact conduction jig according to one non-limiting aspect of the present disclosure may include: a support plate including a plate-shaped member and having a plurality of through holes extending along a thickness of the support plate; a plurality of tubular bodies each having a tubular shape and that is electrically conductive, the tubular bodies being respectively inserted into the through holes; and a holding member elastically holding the respective tubular bodies in the through holes. In the contact conduction jig, each of the tubular bodies includes a first spring part wound helically in a first direction and configured to expand and contract along an axis of the tubular body.

An inspection device according to another non-limiting aspect of the present disclosure may include: the contact conduction jig described above; and an inspection processing portion configured to electrically connect one end of each tubular body to an inspection point on an inspection object and configured to inspect the inspection object, based on an electric signal from each tubular body.

The contact conduction jig and the inspection device facilitate improvement in their abilities to adapt to variations in height of contact objects.

### BRIEF DESCRIPTION OF DRAWINGS

FIG. 1 is a conceptual view schematically illustrating a configuration of a board inspection device including inspection jigs according to a non-limiting aspect of the present disclosure.

FIG. 2 is a perspective view illustrating another example of an inspection portion illustrated in FIG. 1.

FIG. 3 is a schematic sectional view illustrating examples of configurations of an inspection jig and a base plate illustrated in FIGS. 1 and 2.

FIG. 4 is an explanatory view illustrating the inspection jig that is in contact with the base plate and a semiconductor element.

FIG. 5 is a schematic sectional view illustrating different examples of the configurations of the inspection jig and base plate illustrated in FIG. 3.

FIG. 6A is a conceptual view illustrating examples of a first spring part and a second spring part formed by a three-dimensional metal printer.

FIG. 6B is a conceptual view illustrating the examples of the first spring part and second spring part formed by the three-dimensional metal printer.

### DETAILED DESCRIPTION

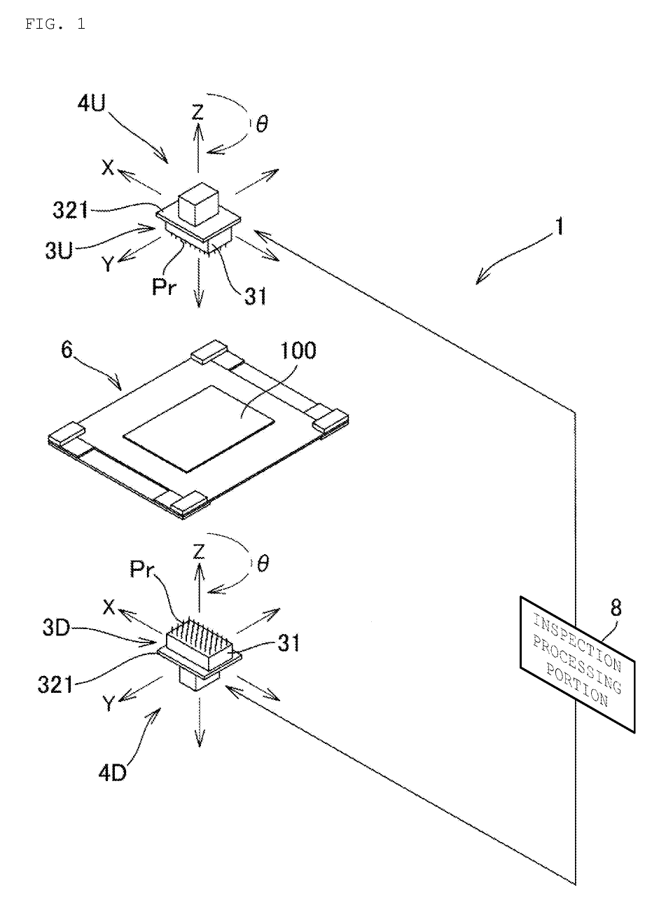

Aspects of the present disclosure will be described below based on the drawings. It should be noted that configurations denoted with the same reference sign in the respective drawings are identical to one another; therefore, the description thereof will not be given. FIG. 1 is a conceptual view schematically illustrating a configuration of a board inspection device 1 including inspection jigs according to a non-limiting aspect of the present disclosure. The board inspection device 1 is a non-limiting example of an inspection device. Each of the inspection jigs 3U and 3D is a non-limiting example of a contact conduction jig. The board inspection device 1 illustrated in FIG. 1 is a device for inspecting a circuit pattern on a board 100, which is a non-limiting example of an inspection object.

Non-limiting examples of the board 100 may include various types of boards such as a printed circuit board; a flexible board; a ceramic multilayer circuit board; an electrode plate for use in a liquid crystal display and a plasma display; a semiconductor substrate; and a package board and a film carrier for use in a semiconductor package. It should be noted that the inspection object is not limited to a board, but may be, for example, an electronic component such as a semiconductor element (e.g., an integrated circuit (IC)) or may be any other object to be subjected to electrical inspection.

The board inspection device 1 illustrated in FIG. 1 includes inspection portions 4U and 4D, a board fixing device 6, and an inspection processing portion 8. The board fixing device 6 is configured to fix the board 100 to be inspected, at a predetermined position. The inspection portions 4U and 4D respectively include the inspection jigs 3U and 3D, and base plates 321 on which the inspection jigs 3U and 3D are disposed. The inspection portions 4U and 4D also respectively include driving mechanisms (not illustrated) that cause the inspection jigs 3U and 3D to move along an x axis, a y axis, and a z axis perpendicular to one another and cause the inspection jigs 3U and 3D to rotate about the z axis.

The inspection portion 4U is placed above the board 100 fixed to the board fixing device 6. The inspection portion 4D is placed below the board 100 fixed to the board fixing device 6. The inspection portions 4U and 4D respectively include the inspection jigs 3U and 3D detachable therefrom and configured to inspect the circuit pattern on the board 100. Hereinafter, the inspection portions 4U and 4D will be collectively referred to as an inspection portion 4 as appropriate.

Each of the inspection jigs 3U and 3D includes a plurality of probes Pr (tubular bodies), and a support plate 31 holding the plurality of probes Pr with a tip portion of each probe Pr directed to the board 100. Each of the probes Pr is an example of a tubular body. Each of the base plates 321 is provided with electrodes that electrically conduct by contact with rear end portions of the probes Pr. Each of the inspection portions 4U and 4D includes a connection circuit (not illustrated) for electrically connecting the rear end portions of the probes Pr to the inspection processing portion 8 via the electrodes on the base plate 321 and switching among the connections.

Each of the probes Pr has a tubular shape. A specific configuration of each probe Pr will be described in detail below. Each of the support plates 31 has a plurality of through holes respectively supporting the probes Pr. The through holes are formed at positions corresponding to positions of inspection points defined on a wiring pattern on the board 100 to be inspected. With this configuration, the tip portions of the probes Pr are brought into contact with inspection points on the board 100. For example, the probes Pr are disposed on intersections in a grid. The sides of the grid respectively extend along the x axis and the y axis perpendicular to each other. Non-limiting examples of the inspection points may include a wiring pattern, a solder bump, and a connection terminal.

The inspection jigs 3U and 3D are similar in configuration to each other, except for the following respects. Firstly, the probes Pr on the inspection jig 3U are different in arrangement from the probes Pr on the inspection jig 3D. Secondly, the inspection jig 3U is disposed below the inspection portion 4U, whereas the inspection jig 3D is disposed above the inspection portion 4D. Hereinafter, the inspection jigs 3U and 3D will be collectively referred to as an inspection jig 3 as appropriate. The inspection jig 3 is replaceable in accordance with the board 100 to be inspected.

The inspection processing portion 8 may include, for example, a power supply circuit, a voltmeter, an ammeter, and a microcomputer. The inspection processing portion 8 controls the driving mechanisms (not illustrated) to move and position the inspection portions 4U and 4D and to bring the tip portions of the probes Pr into contact with the inspection points on the board 100. With this configuration, the inspection processing portion 8 is electrically connected to the inspection points. In this state, the inspection processing portion 8 feeds a current or voltage for inspection to the inspection points on the board 100 via the probes Pr of the inspection jig 3, and inspects the board 100 for, for example, a disconnection or a short circuit on the circuit pattern, based on a voltage signal or current signal from each of the probes Pr. Alternatively, the inspection processing portion 8 may feed an alternating current or voltage to the inspection points, thereby measuring impedance to be inspected, based on a voltage signal or current signal from each of the probes Pr.

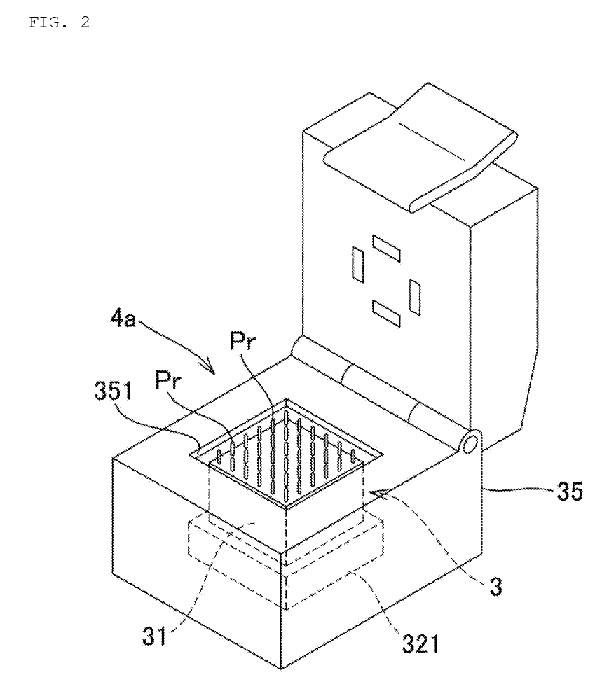

FIG. 2 is a perspective view illustrating another example of the inspection portion 4 illustrated in FIG. 1. An inspection portion 4a illustrated in FIG. 2 includes a so-called IC socket 35 and an inspection jig 3 (contact conduction jig) installed in the IC socket 35. The inspection portion 4a does not include a driving mechanism, unlike the inspection portion 4, and probes Pr are brought into contact with pins, bumps, or electrodes on an IC mounted on the IC socket 35. An inspection device that includes the inspection portion 4a rather than the inspection portions 4U and 4D illustrated in FIG. 1 may serve as an IC inspection device for inspecting a semiconductor element (e.g., an IC) which is an example of an inspection object.

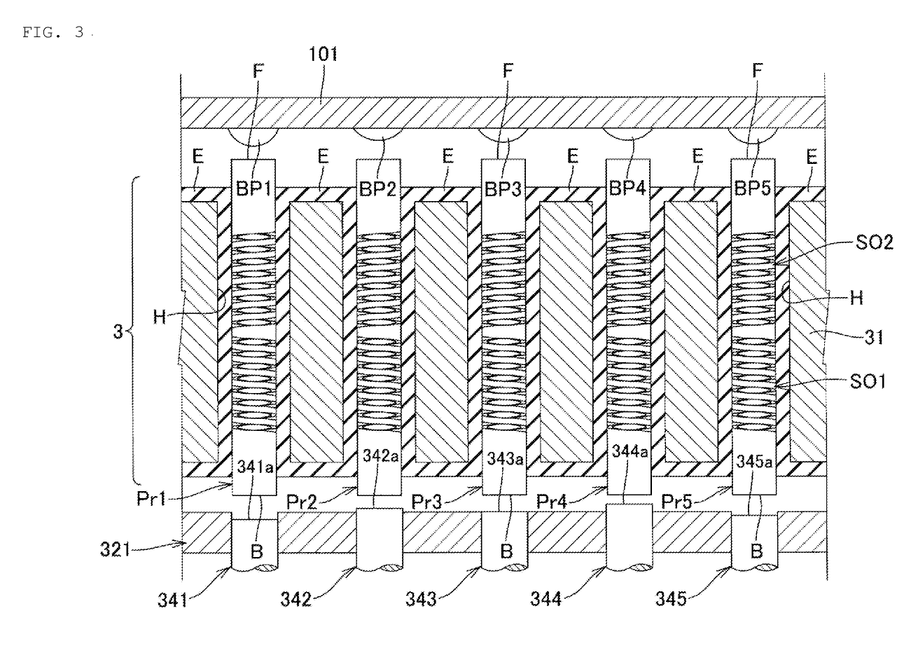

FIG. 3 is a schematic sectional view illustrating examples of configurations of the inspection jig 3 and base plate 321 illustrated in FIGS. 1 and 2. The inspection jig 3 illustrated in FIG. 3 is installed in the inspection portion 4a illustrated in FIG. 2, and an inspection object illustrated in FIG. 3 is a semiconductor element 101.

The inspection jig 3 illustrated in FIG. 3 includes: a support plate 31 that includes a plate-shaped member and has a plurality of through holes H extending along the thickness of the support plate 31; probes Pr1 to Pr5 (tubular bodies) that are probes Pr each formed in a tubular shape and respectively inserted into the through holes H; and an elastomer E that is interposed between an inner wall of each through hole H and an outer periphery of the corresponding probe Pr in the through hole H. In the example illustrated in FIG. 3, the elastomer E covers opposite faces of the support plate 31.

The elastomer E elastically holds each probe Pr in the corresponding through hole H. The probes Pr are elastically held in the through holes H, and therefore are movable axially against the elastic force of the elastomer E. Non-limiting examples of the elastomer E may include various elastic materials. However, from the viewpoint of facilitating the movement of the probes Pr in the through holes H, the elastomer E may suitably be a foamed elastomer that is an elastic material containing micro air bubbles dispersed throughout this material. The foamed elastomer facilitates, because of its high flexibility, the movement of the probes Pr in the through holes H.

The base plate 321 is made of, for example, an insulating resin material, and is disposed near a rear end of the support plate 31. In the base plate 321, wires 341 to 345 are disposed at positions opposite to rear end portions of the probes Pr1 to Pr5 so as to penetrate the base plate 321. Hereinafter, the wires 341 to 345 will be collectively referred to as a wire 34 as appropriate.

A surface of the base plate 321 opposite to the support plate 31 is made flush with end faces of the wires 341 to 345 exposed to the surface, by processing. The end faces of the wires 341 to 345 form electrodes 341a to 345a. However, the surface of the base plate 321 is not flush with the electrodes 341a to 345a depending on, for example, processing accuracy, which may cause variations in position of the electrodes 341a to 345a. Hereinafter, the electrodes 341a to 345a will be collectively referred to as an electrode 34a as appropriate.

The probes Pr are respectively inserted into the through holes H. Each of the probes Pr may be an electrically conductive tubular member. Each of the probes Pr may include: a first spring part SO1 wound helically in a first direction and configured to expand and contract along an axis of the probe Pr; and a second spring part SO2 wound helically in a second direction opposite to the first direction. The first spring part SO1 is substantially identical in number of turns and line width to the second spring part SO2.

The probes Pr may be made of, for example, nickel or a nickel alloy. The first spring part SO1 and the second spring part SO2 in each probe Pr may be formed by any method. For example, these spring parts may be formed in such a manner that a helical slit is formed by etching in a peripheral wall of a tubular member. For example, these spring parts may be formed in such a manner that a helical slit is formed by electroforming in a peripheral wall of a tubular member. For example, these spring parts may be formed by a so-called three-dimensional metal printer. For example, these spring parts may be formed by photolithography. As described above, various manufacturing methods may be employed for forming the spring parts.

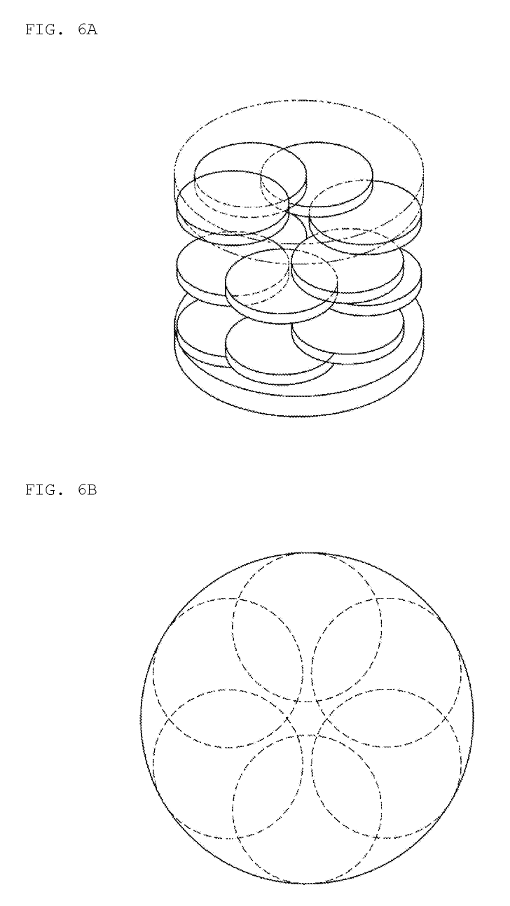

FIGS. 6A and 6B are conceptual views each illustrating examples of a first spring part SO1 and a second spring part SO2 formed by a three-dimensional metal printer. Specifically, FIG. 6A is a perspective view, and FIG. 6B is a top view. As illustrated in FIGS. 6A and 6B, the first spring part SO1 and the second spring part SO2 may be formed by the three-dimensional printer in such a manner that a plurality of metal disks are helically stacked in sequence.

In expansion and contraction, each of the first spring part SO1 and the second spring part SO2 tends to turn around its axis in relation to the expansion and contraction. In bringing each of the probes Pr into press-contact with the corresponding inspection point or in separating each of the probes Pr from the corresponding inspection point, therefore, each of the first spring part SO1 and the second spring part SO2 contracts or expands to generate a force causing the corresponding probe Pr to rotate about its axis.

The first spring part SO1 and the second spring part SO2 are wound in opposite directions, are substantially equal in line width at a spring portion (helical portion) to each other, and are substantially equal in number of turns to each other. Therefore, a rotational force from the first spring part SO1 and a rotational force from the second spring part SO2 are opposite in direction to each other and are substantially equal in magnitude to each other. Consequently, the rotational force from the first spring part SO1 and the rotational force from the second spring part SO2 are offset, so that the rotation of the corresponding probe Pr is suppressed.

Each of the probes Pr is held in the corresponding through hole H by the elastomer E with which the through hole H is filled. Therefore, the elastic force of the elastomer E prevents the rotation of each probe Pr. Consequently, the first spring part SO1 and the second spring part SO2 are less likely to contract or expand. As to the probes Pr, however, since the rotation of each probe Pr is suppressed, the contraction or expansion of the probe Pr is facilitated. It should be noted that each of the probes Pr does not necessarily include both the first spring part SO1 and the second spring part SO2. Alternatively, each of the probes Pr may include one of the first spring part SO1 and the second spring part SO2.

For example, each of the probes Pr not contracting may be set to have a length of 10 mm to 30 mm, e.g., about 20 mm. For example, each of the probes Pr may be set to have an outer diameter of about 25 to 300 μm, e.g., about 100 μm.

The support plate 31 has a thickness less than the length of each probe Pr not contracting. Both the ends of each probe Pr protrude from the opposite faces of the support plate 31 in a state in which the inspection jig 3 is out of contact with the base plate 321 and the semiconductor element 101. In this state, when the inspection jig 3 is mounted on the base plate 321, the rear end portion B of each probe Pr is brought into contact with the corresponding electrode 34a by the biasing force of the corresponding first spring part SO1, second spring part SO2, and elastomer E.

With this configuration, each probe Pr and the corresponding electrode 34a are brought into electrical contact, so that each of the probes Pr is electrically connected to the inspection processing portion 8 via the corresponding wire 34. Then, when the semiconductor element 101 is mounted on the IC socket 35, the inspection points, for example, bumps BP1 to BP5 on the semiconductor element 101 are brought into contact with the tip portions F of the probes Pr1 to Pr5. With this configuration, the bumps BP1 to BP5, which are the inspection points, are electrically connected to the inspection processing portion 8. Hereinafter, the bumps BP1 to BP5 will be collectively referred to as a bump BP as appropriate.

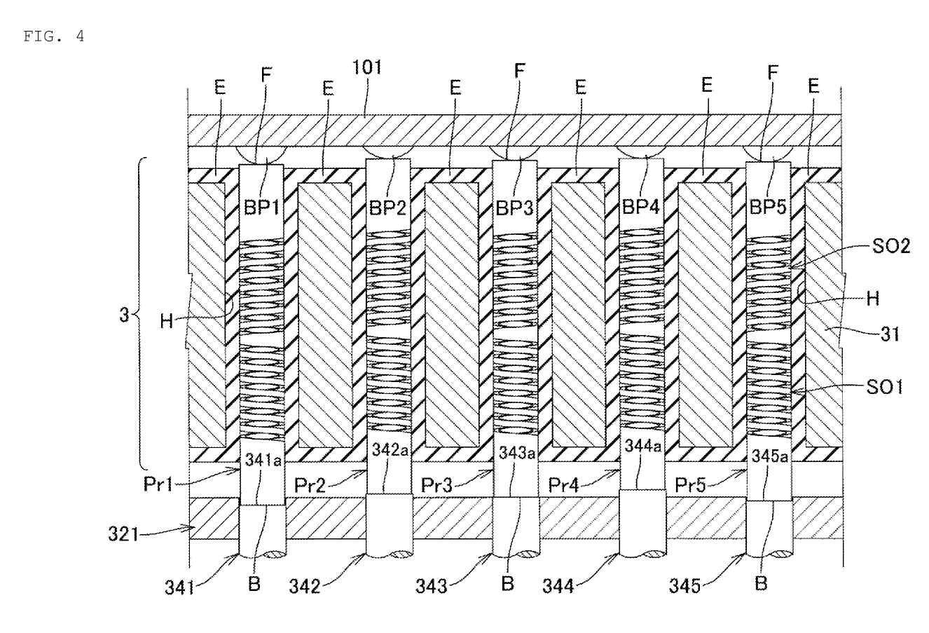

FIG. 4 is an explanatory view illustrating the inspection jig 3 that is in contact with the base plate 321 and the semiconductor element 101. The bumps BP1 to BP5 on the semiconductor element 101 are different in height from one another due to variations in manufacture of the bumps BP1 to BP5. In the example illustrated in FIG. 4, the bump BP1 has a larger amount of protrusion (i.e., the bump BP1 is longer), and the bump BP4 has a smaller amount of protrusion (i.e., the bump BP4 is shorter). In addition, the electrodes 341a to 345a are different in position from one another as described above. In the example illustrated in FIG. 4, the electrode 341a is more recessed (i.e., the electrode 341a is shorter), and the electrode 344a has a larger amount of protrusion (i.e., the electrode 344a is longer).

It is assumed herein that the positions of the probes Pr are fixed in the through holes H. In this case, the rear end portion B of the probe Pr1 has a shortage of the amount of protrusion. For this reason, occasionally, the rear end portion B of the probe Pr1 is pressed against the electrode 341a by a weaker biasing force or is not brought into contact with the electrode 341a. In the case where the positions of the probes Pr are fixed in the through holes H, the tip portion F of the probe Pr1 is brought into contact with the bump BP1 having the larger amount of protrusion. For this reason, the first spring part SO1 and the second spring part SO2 fail to adapt to the amount of protrusion of the bump BP1. Occasionally, pressure at the contact portion between the tip portion F and the bump BP1 causes damage to the tip portion F and the bump BP1.

In contrast to this, the inspection jig 3 illustrated in FIG. 4 has the configuration in which each of the probes Pr is elastically held in the corresponding through hole H by the elastomer E. Therefore, when the tip portion F of the probe Pr1 is brought into contact with the bump BP1 having the larger amount of protrusion, the entire probe Pr1 moves toward the electrode 341a. This configuration increases the pressure to bring the rear end portion B of the probe Pr1 into contact with the electrode 341a, and decreases the pressure to bring the tip portion F of the probe Pr1 into contact with the bump BP1. This configuration therefore improves stability in contact of the probe Pr1 with the electrode 341a and the bump BP1.

Likewise, when the rear end portion B of the probe Pr4 is brought into contact with the electrode 344a having the larger amount of protrusion, the entire probe Pr4 moves toward the bump BP4. This configuration therefore improves stability in contact of the probe Pr4 with the electrode 344a and the bump BP4. As described above, the inspection jig 3 is capable of improving its ability to adapt to variations in height of the bumps BP, each of which is a contact object, and variations in height of the electrodes 34a, each of which is a contact object.

Each of the rear end portions B may be closed with a first closure portion that is electrically conductive, and each of the tip portions F is closed with a second closure portion that is electrically conductive. The first closure portion and the second closure portion may be cap-shaped members made of metal and formed such that the rear end portion B and the tip portion F are covered therewith. Alternatively, the rear end portion B and tip portion F of each probe Pr may be melted and closed by, for example, welding.

Each of the probes Pr formed in a tubular shape has a small contact area since the annular end faces respectively come into contact with the corresponding bump BP and the corresponding electrode 34a unless the rear end portion B and the tip portion F are closed. Hence, the first closure portion and the second closure portion are provided to increase the contact area of each probe Pr with the corresponding bump BP and the contact area of each probe Pr with the corresponding electrode 34a. This configuration improves the stability in contact of each probe Br with the corresponding bump Br and electrode 34a.

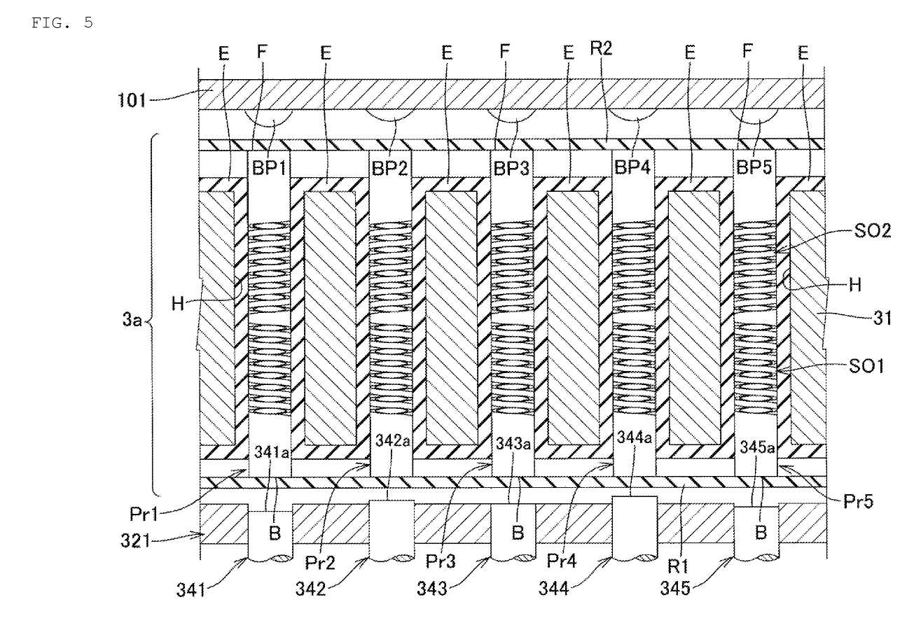

As illustrated in FIG. 5, the inspection jig 3a may further include, as a holding member, an anisotropic conductive sheet R1 (first anisotropic conductive sheet) that exhibits electrical conductivity and elasticity along the thickness thereof and is disposed such that a surface thereof is in contact with the rear end portions B of the probes Pr, and an anisotropic conductive sheet R2 (second anisotropic conductive sheet) that exhibits electrical conductivity and elasticity along the thickness thereof and is disposed such that a surface thereof is in contact with the tip portions F of the probes Pr.

Each of the anisotropic conductive sheets R1 and R2 may be formed of, for example, a sheet-shaped elastomer material in which conductive particles, such as metal particles or carbon particles, are mixed and are arranged along the thickness of this material. With this configuration, each of the anisotropic conductive sheets R1 and R2 is of high electric resistance and exhibits no electrical conductivity along its plane, but is of low electric resistance and exhibits electrical conductivity along its thickness.

In the inspection jig 3a, the rear end portion B of each probe Pr is brought into contact with the corresponding electrode 34a via the anisotropic conductive sheet R1 having elasticity, and the tip portion F of each probe Pr is brought into contact with the corresponding bump BP via the anisotropic conductive sheet R2 having elasticity. This configuration therefore improves the stability in contact of each probe Pr with the corresponding electrode 34a and bump BP. Particularly, in a case where each of the probes Pr is not provided with the first and second closure portions, the anisotropic conductive sheets R1 and R2 are provided to improve the stability in contact of each probe Pr with the corresponding electrode 34a and bump BP.

Alternatively, the inspection jig 3a may have a configuration in which the probes Pr are held in the through holes H by the anisotropic conductive sheets R1 and R2 serving as a holding member, rather than by the elastomer E serving as a holding member.

The inspection jig 3 for use in a board inspection device has been described as an example of a connection jig. However, the connection jig is not limited to an inspection jig, but is applicable in instances in which a connection terminal may be brought into contact with a target object. In addition, each of the contact conduction jigs is not limited to an inspection jig, and each of the tubular bodies is not limited to a probe for inspection. Examples of the contact conduction jigs may include a connection terminal and a connector for establishing an electrical connection between two points.

In summary, a contact conduction jig according to a non-limiting aspect of the present disclosure may include: a support plate including a plate-shaped member and having a plurality of through holes extending along a thickness of the support plate; a plurality of tubular bodies each having a tubular shape and electrical conductivity, the tubular bodies being respectively inserted into the through holes; and a holding member elastically holding the respective tubular bodies in the through holes. In the contact conduction jig, each of the tubular bodies may include a first spring part wound helically in a first direction and be configured to expand and contract along an axis of the tubular body.

With this configuration, each of the tubular bodies is elastically held in the corresponding through hole by the holding member. Each of the tubular bodies is therefore movable in the corresponding through hole against the elastic force of the holding member. Consequently, the contact conduction jig is capable of adapting to variations in height of contact objects by the expansion and contraction of the first spring parts and the movement of the tubular bodies. The contact conduction jig therefore facilitates improvement in its ability to adapt to the variations in height of the contact objects.

The holding member may include an elastomer interposed between an inner wall of each through hole and an outer periphery of the corresponding tubular body in the through hole.

The elastomer may be interposed between the inner wall of the each through hole and the outer periphery of the corresponding tubular body in the through hole to elastically hold the tubular body in the through hole. The elastomer, therefore, may be suitable as the holding member.

The holding member may include: a first anisotropic conductive sheet exhibiting electrical conductivity and elasticity along a thickness thereof, the first anisotropic conductive sheet being disposed such that a surface thereof is in contact with a first end of each tubular body; and a second anisotropic conductive sheet exhibiting electrical conductivity and elasticity along a thickness thereof, the second anisotropic conductive sheet being disposed such that a surface thereof is in contact with a second end of each tubular body.

The first anisotropic conductive sheet exhibiting electrical conductivity and elasticity along the thickness thereof may be disposed such that the surface thereof is in contact with the first ends of the tubular bodies, to elastically hold the tubular bodies in the through holes. In addition, the second anisotropic conductive sheet exhibiting electrical conductivity and elasticity along the thickness thereof may be disposed such that the surface thereof is in contact with the second ends of the tubular bodies, to elastically hold the tubular bodies in the through holes. Each of the first anisotropic conductive sheet and the second anisotropic conductive sheet, therefore, may be suitable as the holding member. Moreover, the first ends of the tubular bodies may be in contact with the contact objects via the first anisotropic conductive sheet having elasticity, and the second ends of the tubular bodies may be in contact with the contact objects via the second anisotropic conductive sheet having elasticity. This configuration improves stability in contact of the tubular bodies with the contact objects.

The contact conduction jig may further include: a first closure portion having electrical conductivity and closing a first end of a corresponding one of the tubular bodies; and a second closure portion having electrical conductivity and closing a second end of the corresponding tubular body.

Each of the tubular bodies may be formed in a tubular shape and, therefore, may have a small contact area since the annular end faces of each tubular body respectively come into contact with the contact objects unless the opposite ends of each tubular body are closed. Hence, the first closure portion and the second closure portion may be provided to increase the contact area of each tubular body with the contact objects. This configuration improves the stability in contact of each tubular body with the contact objects.

Each of the tubular bodies may further include a second spring part wound helically in a second direction opposite to the first direction and configured to expand and contract along the axis of the tubular body.

In expansion and contraction, each of the first spring part and the second spring part tends to turn around its axis in relation to the expansion and contraction. In bringing the tubular bodies into press-contact with the contact objects or in separating the tubular bodies from the contact objects, therefore, each of the first spring part and the second spring part contracts or expands to generate a force causing the corresponding tubular body to rotate about its axis. The first spring part and the second spring part are wound in opposite directions. Therefore, a rotational force from the first spring part is opposite in direction to a rotational force from the second spring part. Consequently, the rotational force from the first spring part and the rotational force from the second spring part are offset, so that the rotation of the corresponding tubular body is suppressed. Each of the tubular bodies may be elastically held in the corresponding through hole by the holding member. Therefore, the holding member prevents the rotation of the tubular bodies. Consequently, the first spring part and the second spring part are less likely to contract or expand. However, this configuration suppresses the rotation of the tubular bodies, and therefore facilitates the contraction or expansion of the tubular bodies.

The first spring part may be substantially equal in number of turns to the second spring part.

This configuration improves accuracy in offsetting the rotational forces, and therefore facilitates the contraction or expansion of the tubular bodies.

An inspection device according to another non-limiting aspect of the present disclosure may include: the contact conduction jig described above; and an inspection processing portion configured to electrically connect one end of each tubular body to an inspection point on an inspection object and configured to inspect the inspection object, based on an electric signal from each tubular body.

This configuration facilitates improvement in ability to adapt to variations in height of the inspection points which are contact objects.

### REFERENCE SIGNS LIST

1: board inspection device (inspection device)
3, 3a, 3U, 3D: inspection jig (contact conduction jig)
4, 4a, 4U, 4D: inspection portion
6: board fixing device
8: inspection processing portion
31: support plate
34, 341 to 345: wire
34a, 341a to 345a: electrode
35: IC socket
100: board (inspection object)
101: semiconductor element (inspection object)
321: base plate
B: rear end portion
BP, BP1 to BP5: bump (inspection point)
E: elastomer (holding member)
F: tip portion
H: through hole
Pr, Pr1 to Pr5: probe (tubular body)
R1: anisotropic conductive sheet (first anisotropic conductive sheet)
R2: anisotropic conductive sheet (second anisotropic conductive sheet)
SO1: first spring part
SO2: second spring part

1. A contact conduction jig comprising:
a support plate comprising a plate-shaped member and a plurality of through holes extending along a thickness of the support plate;
a plurality of tubular bodies that are each electrically conductive, each tubular body of the plurality of tubular bodies inserted into a respective through hole of the plurality of through holes; and
a holding member elastically holding the plurality of tubular bodies in the respective through holes of the plurality of through holes,
wherein
each tubular body of the plurality of tubular bodies comprises a first spring part wound helically in a first direction and configured to expand and contract along an axis of the tubular body.

2. The contact conduction jig according to claim 1, wherein
the holding member comprises an elastomer interposed between an inner wall of each through hole of the plurality of through holes and an outer periphery of a corresponding tubular body of the plurality of tubular bodies in the through hole.

3. The contact conduction jig according to claim 1, wherein
the holding member comprises:
a first anisotropic conductive sheet having electrical conductivity and elasticity along a thickness thereof, the first anisotropic conductive sheet disposed such that a surface thereof is in contact with a first end of each tubular body of the plurality of tubular bodies; and
a second anisotropic conductive sheet having electrical conductivity and elasticity along a thickness thereof, the second anisotropic conductive sheet being disposed such that a surface thereof is in contact with a second end of each tubular body.

4. The contact conduction jig according to claim 1, wherein
each tubular body of the plurality of tubular bodies further comprises:
a first closure portion having electrical conductivity and closing a first end of the tubular body; and
a second closure portion having electrical conductivity and closing a second end of the tubular body.

5. The contact conduction jig according to claim 1, wherein
each tubular body of the plurality of tubular bodies further comprises a second spring part wound helically in a second direction opposite to the first direction and configured to expand and contract along the axis of the tubular body.

6. The contact conduction jig according to claim 5, wherein
the first spring part has a substantially equal number of turns as the second spring part.

7. An inspection device comprising:
the contact conduction jig according to claim 1; and
an inspection processing portion configured to electrically connect one end of each tubular body of the plurality of tubular bodies to an inspection point on an inspection object and is further configured to inspect the inspection object, based on an electric signal from each tubular body of the plurality of tubular bodies.

8. The contact conduction jig according to claim 2, wherein
the elastomer comprises an elastic material and micro air bubbles dispersed throughout the elastic material.

9. The contact conduction jig according to claim 1, wherein
a biasing force on each tubular body of the plurality of tubular bodies is based on a biasing force of the first spring part and a biasing force of the holding member.

10. The contact conduction jig according to claim 5, wherein
a biasing force on each tubular body of the plurality of tubular bodies is based on a biasing force of the first spring part, a biasing force of the second spring part, and a biasing force of the holding member.

11. The contact conduction jig according to claim 3, wherein
the first anisotropic conductive sheet and the second anisotropic conductive sheet comprise metal particles arranged along the respective thicknesses thereof.

12. The contact conduction jig according to claim 3, wherein
the first anisotropic conductive sheet and the second anisotropic conductive sheet comprise carbon particles arranged along the respective thicknesses thereof.

13. The contact conduction jig according to claim 3, wherein
each tubular body of the plurality of tubular bodies further comprises:
a first closure portion having electrical conductivity and closing a first end of the tubular body; and
a second closure portion having electrical conductivity and closing a second end of the tubular body.

14. The contact conduction jig according to claim 2, wherein
the holding member further comprises:
a first anisotropic conductive sheet having electrical conductivity and elasticity along a thickness thereof, the first anisotropic conductive sheet disposed such that a surface thereof is in contact with a first end of each tubular body of the plurality of tubular bodies; and
a second anisotropic conductive sheet having electrical conductivity and elasticity along a thickness thereof, the second anisotropic conductive sheet being disposed such that a surface thereof is in contact with a second end of each tubular body.

15. The contact conduction jig according to claim 14, wherein
each tubular body of the plurality of tubular bodies further comprises:
a first closure portion having electrical conductivity and closing a first end of the tubular body; and
a second closure portion having electrical conductivity and closing a second end of the tubular body.

16. The contact conduction jig according to claim 14, wherein
each tubular body of the plurality of tubular bodies further comprises a second spring part wound helically in a second direction opposite to the first direction and configured to expand and contract along the axis of the tubular body.

17. The contact conduction jig according to claim 16, wherein
the first spring part has a substantially equal number of turns as the second spring part.

18. An inspection device comprising:
the contact conduction jig according to claim 4; and
an inspection processing portion configured to electrically connect one end of each tubular body of the plurality of tubular bodies to an inspection point on an inspection object and is further configured to inspect the inspection object, based on an electric signal from each tubular body of the plurality of tubular bodies.

19. An inspection device comprising:
the contact conduction jig according to claim 14; and
an inspection processing portion configured to electrically connect one end of each tubular body of the plurality of tubular bodies to an inspection point on an inspection object and is further configured to inspect the inspection object, based on an electric signal from each tubular body of the plurality of tubular bodies.

20. An inspection device comprising:
the contact conduction jig according to claim 17; and
an inspection processing portion configured to electrically connect one end of each tubular body of the plurality of tubular bodies to an inspection point on an inspection object and is further configured to inspect the inspection object, based on an electric signal from each tubular body of the plurality of tubular bodies.
